(19) United States
(12) Patent Application Publication
(10) Pub. No.: US 2008/0164927 A1
(43) Pub. Date: Jul. 10, 2008

(54) Low-Phase Noise Low-Power Accurate I/Q Generator Using A Dynamic Frequency Divider

(75) Inventor: Xudong Wang, Groton, MA (US)

Correspondence Address: DOWNS RACHLIN MARTIN PLLC, 199 MAIN ST, PO BO 190, BURLINGTON, VT, 05402-0190, US

(73) Assignee: International Business Machines Corporation, Armonk, NY (US)

(21) Appl. No.: 11/621,258

(22) Filed: Jan. 9, 2007

(51) Int. Cl. H03K 3/00; G06F 1/04

(52) U.S. Cl. 327/254; 327/295; 327/258

(57) ABSTRACT

A signal generator and method for generating a plurality of signals of differing phase. The signal generator comprises a first single-phase frequency divider locked with a 90° phase shift that includes a first output port providing a first output signal and a first internal node providing a first internal signal, a second single-phase frequency divider locked with a 90° phase shift that includes a second output port providing a second output signal and a second internal node providing a second internal signal, and a first feedback circuit. The first feedback circuit coupled between either: first and second output ports or first and second internal nodes. The first feedback circuit configured to phase-lock first and second output signals 180° apart when the first feedback circuit is coupled between first and second outputs ports and phase-lock first and second internal signals 180° apart when the first feedback circuit is coupled between first and second internal nodes.

### FIELD OF THE INVENTION

The present invention generally relates to the field of wireless communications. In particular, the present invention is directed to a low-phase noise low-power accurate in-phase/quadrature-phase (I/Q) generator using a dynamic frequency divider.

### BACKGROUND OF THE INVENTION

Demand for high speed, low cost, and small form factor communications circuits has rapidly grown along with the usage and popularity of wireless devices, such as personal cellular phones. As a result, the wireless industry has attempted to continuously improve performance of such wireless devices.

Highly-integrated transceivers provide cost savings in wireless communication applications over conventional multi-chip superheterodyne architecture and configurations. Such highly integrated transceivers require accurate in-phase/quadrature-phase (I/Q) signal generation for both a modulator and a demodulator of the wireless device. I/Q signals may be generated with three techniques: with a frequency divider, with polyphase filters, or with quadrature voltage controlled oscillators (QVCO). In modern wireless systems, system-on-chip (SOC) and low cost, low-power requirement favors direct conversion topology (homodyne architecture) in both the receiver and transmitter. In direct conversion topology, it is preferred that the local oscillator frequency is different from the operation frequency to avoid its frequency being pulled by the power amplifier. This requirement makes the use of the polyphase filter technique and the QVCO methods unfavorable. In addition to the frequency pulling issue, other issues may also exist for these two methods, such as issues with power consumption and I/Q accuracy.

In the polyphase filter technique, a driver is needed to compensate for the loss from the filter, which results in more power consumption. In the quadrature VCO technique, the I/Q phase is hard to maintain because of layout restraints between two coupled VCO inductors and layout parasitics. As a result, frequency divider technique is a popular method for generating I/Q signals in direct conversion wireless systems. Although I/Q signals can be generated by D flip-flop style frequency dividers, a very low phase noise with low power consumption is difficult to achieve. For example, a GSM transmitter requires such a low phase noise at −165 dBc/Hz phase noise at 20 MHz offset frequency.

Divide-by-two circuits (DTCs), as well known in the art, are widely used to produce quadrature outputs. DTCs may follow a VCO in a phase-locked loop to lower the frequency to a range that can be applied to a programmable divider with small steps since DTCs achieve a higher speed than dividers with other division factors. DTC may be realized as two latches in a negative feedback loop.

FIG. 7 illustrates a CMOS inverter 700 with an inverted output. Inverter 700 includes a first latch 710 and a second latch 720 for producing quadrature phase signals, D and Q bar. First latch 710 and second latch 720 are controlled by a clock signal 730 and a clock bar signal 740, respectively. The implementation of latches depends on the type of transistors. Proper sizing of the transistors in this configuration results in a reasonable speed-power trade-off at gigahertz rates. Additionally, quadrature phases D and Q bar require clock and clock bar signals 730, 740 to be precisely complementary with first and second latches 710, 720 matching perfectly. Typical device mismatches result in phase imbalances as large as 5°. Moreover, if clock and clock bar signals 730, 740 do not match exactly differential, additional phase imbalance may result.

A conventional high-speed dynamic CMOS divider 800 is illustrated in FIG. 8. CMOS divider 800 includes a first inverter 810, a second inverter 820, and a third inverter 830. First and second inverters 810, 820 operate as dynamic latches controlled by a clock signal 840 and a clock bar signal 850. Third inverter 830 provides an overall inversion required in the negative feedback loop.

Another conventional dynamic CMOS divider 900 is provided in FIG. 9. Divider 900 includes a first latch 910, a second latch 920, and a first inverter 930 controlled by a clock signal 940 and a clock bar signal 950.

Frequency dividers 800 and 900 perform well for high-speed and low power divider. However, dividers 800 and 900 each lack precise complementary or quadrature outputs. Additionally, both dividers 800 and 900 can only output a single-ended signal, where precise complementary or quadrature outputs are difficult to generate.

Therefore, there is a need in the art for generating accurate I/Q signals with low-power, low-phase noise, and low noise floors.

### SUMMARY OF THE INVENTION

In one aspect of the present disclosure an integrated circuit is provided. The integrated circuit includes a signal generator for generating a plurality of signals of differing phase, including: a first single-phase frequency divider that includes a first output port for providing a first output signal and a first internal node for providing a first internal signal, a second single-phase frequency divider that includes a second output port for providing a second output signal and a second internal node for providing a second internal signal, and first feedback circuit coupled between either: 1) the first output port and the second output port or 2) the first internal node and the second internal node, the first feedback circuit configured to phase-lock the first output signal and the second output signal 180° apart when the first feedback circuit is coupled between the first output port and the second output port and phase-lock the first internal signal and the second internal signal 180° apart when the first feedback circuit is coupled between the first internal node and the second internal node.

In another aspect of the present disclosure an I/Q signal generator is provided. The I/Q signal generator includes signal generation circuit responsive to a clock signal and a clock-bar signal so as to generate an in-phase signal and a quadrature-phase signal, the signal generation circuit including: a plurality of single-phase frequency dividers each including an output port for providing an output signal and an internal node for providing an internal signal, an in-phase output line and a quadrature-phase output line each in direct communication with differing ones of the output ports and the internal nodes, and first and second 180° phase-lock circuit each coupled between ones of the plurality single-phase frequency dividers so that the in-phase signal outputs the in-phase signal and the quadrature-phase output line outputs the quadrature-phase signal.

In yet another aspect of the present disclosure a method of generating an in-phase signal and a corresponding quadrature-phase signal is provided. The method includes receiving a clock signal having a frequency, generating an in-phase signal as a function of the clock signal so that the in-phase signal has a frequency equal to one-half of the frequency of the clock signal, generating a quadrature-phase signal as a function of the clock signal so that the quadrature-phase signal has a frequency equal to one-half of the frequency of the clock signal, phase-locking the in-phase signal to a complementary in-phase signal, and phase-locking the quadrature-phase signal to a complementary quadrature-phase signal.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a high-level block diagram illustrating an integrated circuit incorporating a plurality of signal generation circuits each made in accordance with the present invention;

FIG. 2 is a high-level schematic diagram illustrating a signal generation circuit suitable for use as any one of the signal generation circuits of FIG. 1;

FIG. 3 is a schematic diagram illustrating a feedback circuit suitable for use in any one of the signal generation circuits of FIGS. 1 and 2;

FIG. 4 is a high-level schematic diagram illustrating an alternative signal generation circuit, made in accordance with the present invention;

FIG. 5 is a high-level schematic diagram illustrating yet another signal generation circuit made in accordance with the present invention;

FIG. 6 is a high-level schematic diagram illustrating still another signal generation circuit made in accordance with the present invention;

FIG. 7 is a schematic diagram illustrating a conventional latch with an inverted output;

FIG. 8 is a schematic diagram illustrating a conventional dynamic CMOS divider; and

FIG. 9 is a schematic diagram illustrating another conventional dynamic CMOS divider.

### DETAILED DESCRIPTION

The present disclosure relates to the field of signal generation. Specifically, the present disclosure provides signal generators for producing accurate in-phase and quadrature phase (I/Q) signals for use, e.g., in wireless communications. The performance of wireless communication devices, such as cell phones, can be optimized when the I/Q signals are accurate with a very low-phase noise, low-power consumption, and low-noise floors.

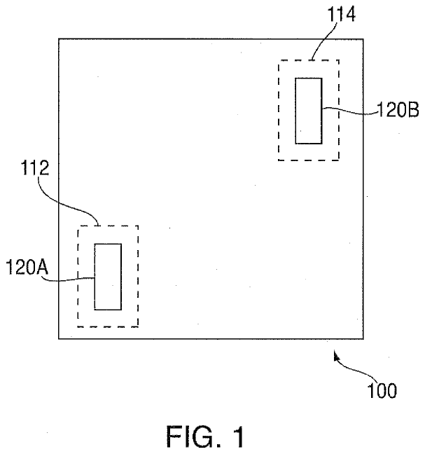

Referring now to the figures, FIG. 1 illustrates an integrated circuit (IC) 100 that may be integrated into wireless communication devices. IC 100 includes, among other things, a receiver 112 and a transmitter 114 for wireless communications. Each of receiver 112 and transmitter 114 includes a corresponding respective signal generator 120A-B, which may be in-phase and quadrature phase (I/Q) signal generator. Signal generators 120A-B of the present disclosure produce accurate I/Q signals (not shown) with low-power, low-phase noise, and low noise floor, as will be described in greater detail below. An IC, such as IC 100, having one or more signal generators of the present disclosure, such as signal generators 120A-B, may also be implemented in other devices such as, but not limited to, computers and other digital devices, where I/Q signals are utilized.

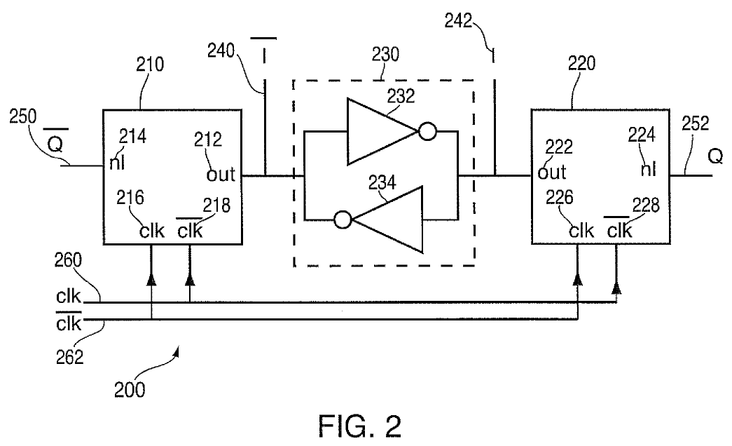

FIG. 2 illustrates a signal generator circuit 200 according to one embodiment of the present disclosure that may be used in a signal generator, such as either of signal generators 120A-B of FIG. 1. Circuit 200 generates a plurality of accurate I/Q signals, e.g., I, Q, I-bar and Q-bar signals, with the same amplitude but differing phases. At a high level, circuit 200 may include, among other things, a first single-phase frequency divider 210, a second single-phase frequency divider 220, and a first feedback circuit 230 coupled between the first and second single-phase frequency dividers. Circuit 200 produces I/Q signals from a clock signal 260 and a clock-bar signal 262, as will be explained below. Clock signal 260 and clock-bar signal 262 have complementary phases and may be provided by an oscillator (not shown), such as a voltage-controlled oscillator (VCO).

First single-phase frequency divider 210 and second single-phase frequency divider 220 are substantially identical and may include a pair of cross-coupled D flip-flop circuits (not shown) in a manner well-known in the art. As those skilled in the art will readily appreciate, first and second single-phase frequency dividers 210, 220 may alternatively include, but are not limited to, other types of edge-triggered flip-flop circuits such as JK flip-flops and T flip-flops, and may be symmetrical or asymmetrical. First single-phase frequency divider 210 may have a first output port 212, a first internal node 214, a first clock input 216, and a first clock-bar input 218. Similarly, second single-phase frequency divider 220 may have a second output port 222, a second internal node 224, a second clock input 226, and a second clock-bar input 228. First internal node 214 and second internal node 224 include a phase shift of 90° relative to first output port 212 and second output port 222, respectively, for producing quadrature signals by each frequency divider 210, 220. For example, the phase shift of 90° is locked in each of first and second frequency dividers 210, 220 by respectively connecting first and second clock inputs 216, 226 with clock bar signal 262 and respectively connecting first and second clock bar inputs 218, 228 with clock signal 260, where the clock signal is a VCO output signal and clock bar signal is a complementary of the VCO output signal.

First feedback circuit 230 may be coupled between first output port 212 and second output port 222. First feedback circuit 230 may be configured to provide a phase-lock of 180° between the signals of first single-phase frequency divider 210 and second single-phase frequency divider 220, here the corresponding respective signals of first output port 212 and second output port 222, i.e., first output signal 240 and second output signal 242. Deviations from the phase shift of 180° would affect the integrity and performance of first output signal 240 and second output signal 242, as well as first internal signal 250 and second internal signal 252.

Alternatively, but not shown, first feedback circuit 230 may be coupled between first internal node 214 and second internal node 224 in another signal generator circuit of the present disclosure. It is noted that the primary difference between connecting first feedback circuit 230 to either first and second output ports 212, 224 or first and second internal nodes 214, 224 is a loading to each frequency divider 210, 220. Cross-coupled frequency dividers, such as first and second frequency dividers 210, 220 may be driven by a current and an associated input capacitance, which may require charging. As a result, it may impact speed (operation frequency), current consumption, and/or phase noise.

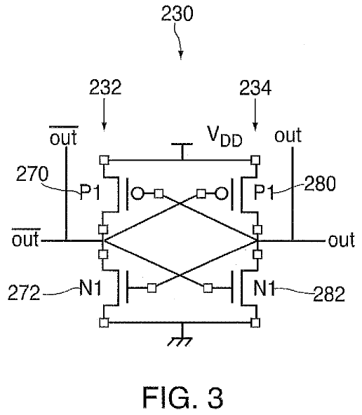

In the embodiment shown, first feedback circuit 230 includes a first inverter 232 cross-coupled to a second inverter 234 for consistently locking the positive feedback loop to a phase shift of 180°. For example, the output of first inverter 232 may go into the input of second inverter 234 and vice versa, such that the output and input of one inverter is the complement of that of the other. More specifically in connection with the illustrative embodiment provided in FIG. 3, first inverter 212 may include a first PFET device 270 and a first NFET device 272, and second inverter 214 may include a second PFET device 280 and a second NFET device 282. It should be noted that other types of inverters may be utilized for first and second inverters 232, 234 while keeping within the scope and spirit of the present disclosure. For example, first and second inverters 232, 234 may include, but are not limited to, a CMOS latch, a single NFET device, and any combination thereof. As those skilled in the art will readily appreciate, since DC current flows through PFET devices 270, 280 and NFET devices 272, 282, the DC current contributes to an output noise and influences a biasing voltage at output port of each frequency divider 210, 220. Thus, the sizing of PFET and NFET devices are chosen carefully based on such factors as how high a current consumption, how high a frequency, and how low a phase noise. Another factor in determining the sizing of the PFETs and NFETs is the type of node used for output ports and internal nodes. Other phase-locking feedback circuits may be used in lieu of cross coupled inverter circuit 230 shown in FIGS. 2 and 3.

Generally, during operation one of the pair of cross-coupled flip-flop circuits of each frequency divider 210, 220 receives and divides clock signal 260. The other flip-flop circuit of each frequency divider 210, 220 receives and divides clock-bar signal 262. First output port 212 provides first output signal 240 and first internal node 214 provides first internal signal 250. First output signal 240 is a complementary in-phase signal (I-bar) relative to first internal signal 250, which is a quadrature signal, i.e., a complementary quadrature-phase signal (Q-bar) relative to the complementary in-phase signal of first internal signal 250. Similarly, second output port 222 provides a second output signal 242 while second internal node 224 provides a second internal signal 252. second output signal 242 is an in-phase signal (I) relative to second internal signal 252, which is a quadrature signal, i.e., a quadrature-phase signal (Q) relative to the in-phase signal of second internal signal 252. Additionally, first feedback circuit 230 phase-locks first output signal 240 to be complementary to second output signal 242, thereby also phase-locking first internal signal 250 to be complementary to second internal signal 252. It is noted that in the context of this disclosure, quadrature signals indicate pairs of signals that have a phase shift of 90° between each signal and complementary signals indicate pairs of signals that have a phase shift of 180° between each signal.

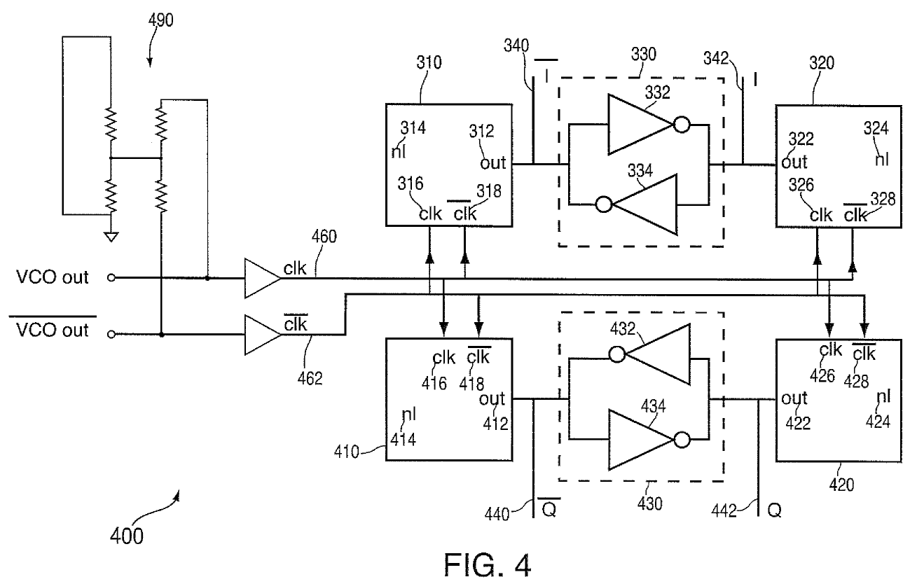

FIG. 4 illustrates a signal generator system 400 according to another embodiment of the present disclosure. System 400 generates a complete set of accurate I/Q signals of differing phases, such as in phase, in phase bar, quadrature phase, and quadrature phase bar signals. System 400 may include, among other things, a first single-phase frequency divider 310, a second single-phase frequency divider 320, a first feedback circuit 330 coupled between the first and second single-phase frequency dividers, a third single-phase frequency divider 410, a fourth single-phase frequency divider 420, and a second feedback circuit 430 coupled between the third and fourth single-phase frequency dividers. System 400 may also include an input amplifier 490 operatively connected to a clock signal 460 and a clock-bar signal 462. Input amplifier 490 amplifies clock signal 460 and clock-bar signal 462 for delivery to frequency dividers 310, 320, 410, 420. Clock signal 460 and clock-bar signal 462 may be provided by an oscillator (not shown), such as a VCO as discussed above.

First, second, third, and fourth single-phase frequency dividers 310, 320, 410, 420 should be substantially identical to each other and similar to frequency dividers 210, 220 provided above in FIG. 2. Hence, first, second, third, and fourth frequency dividers 310, 320, 410, 420 may respectively include: output ports 312, 322, 412, and 422; internal nodes 314, 324, 414, 424; clock inputs 316, 326, 416, 426; and clock-bar inputs 318, 328, 418, 428. Output ports 312, 322, 412, 422 each have a 90° phase shift relative to internal nodes 314, 324, 414, and 424, respectively. The 90° phase shift helps allows each single-phase frequency divider 310, 320, 410, 420 provide a pair of quadrature signals. For example, the phase shift of 90° may be locked in each of first and second frequency dividers 310, 320 by respectively connecting first and second clock inputs 316, 326 with clock bar signal 462 and respectively connecting first and second clock bar inputs 318, 328 with clock signal 460, where the clock signal is a VCO output signal and clock bar signal is a complementary of the VCO output signal. Similarly in third and fourth frequency dividers 410, 420, third and fourth clock inputs 416, 426 connect with clock signal 460 and third and fourth clock bar inputs 418, 428 with clock bar signal 462 to lock a phase shift of 90° in each of the third and fourth frequency dividers.

First, second, third, and fourth single-phase frequency dividers 310, 320, 410, 420 may each include a pair of cross-coupled D flip-flop circuits (not shown). As those skilled in the art will readily appreciate, single-phase frequency dividers 310, 320, 410, 420 may alternatively include, but are not limited to, other types of edge-triggered flip-flop circuits such as JK flip-flops and T flip-flops. In a substantially similar manner as provided above in the discussion of FIG. 2, one of the pairs of cross-coupled flip-flop circuits of each frequency divider 310, 320, 410, 420 receives and divides clock signal 460, while the other flip-flop circuit receives and divides clock-bar signal 462. First, second, third, and fourth single-phase frequency dividers 310, 320, 410, 420 each produce accurate output signals with consistent loading, lower power consumption, and a lower noise floor from symmetrical paths. For example, first frequency divider 310 and first feedback circuit 330 may generate a first output signal 340, second frequency divider 320 and the first feedback circuit may generate a second output signal 342, third frequency divider 410 and second feedback circuit 430 may generate a third output signal 440, and fourth frequency divider 420 and the second feedback circuit may generate a fourth output signal 442. Alternatively, it should be noted, the present disclosure also contemplates first and second feedback circuits 330, 430 coupling with respective internal nodes 314, 324, 414, and 424 to produce output signals 340, 342, 440, 442, respectively, while keeping within the scope and spirit of the present disclosure.

First feedback circuit 330 and second feedback circuit 430 consistently lock a positive feedback loop to a phase shift of 180° between associated single-phase frequency dividers 310, 320, 410, 420. For example, first feedback circuit 330 consistently locks a phase shift of 180° between first output signal 340 and second output signal 342, and second feedback circuit 430 consistently locks a phase shift of 180° between third output signal 440 and fourth output signal 442. Deviations from a phase shift of 180° would affect the integrity and performance of output signals 340, 342, 440, 442. First feedback circuit 330 may include a first inverter 332 cross-coupled with a second inverter 334, and second feedback circuit 430 may include a third inverter 432 cross-coupled with a fourth inverter 434. First, second, third, and fourth inverters 332, 334, 432, 434 may include different types of inverters as discussed above in connection with the illustrative embodiment of FIG. 3.

Furthermore, it is noted system 400 may include single-phase frequency dividers 310, 320, 410, 420 which may be either symmetrical or asymmetrical. Symmetrical single-phase frequency dividers generally have the internal node and the output port as the same node in the frequency divider, such that the internal node and the output port are interchangeable. For asymmetrical frequency dividers such with a CMOS, system 400 may provide inaccurate I/Q signals, where in-phase signals may have different loading than complementary quadrature phase signals, which may result in an inaccurate phase and inaccurate I/Q signals.

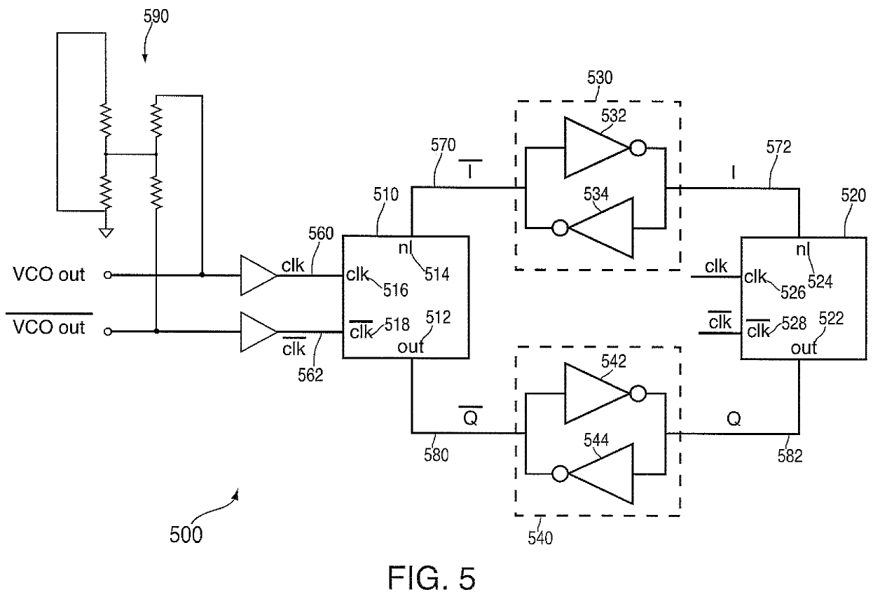

FIG. 5 illustrates yet another embodiment of a signal generator system 500 in accordance with a further embodiment of the present disclosure. System 500 provides accurate I/Q differential signals of differing phases, such as in-phase, in-phase bar, quadrature phase, and quadrature bar phase signals. System 500 includes, among other things, a first symmetrical frequency divider 510, a second symmetrical frequency divider 520, a first feedback circuit 530, and a second feedback circuit 540. First feedback circuit 530 and second feedback circuit 540 may both be coupled between first symmetrical frequency divider 510 and second symmetrical frequency divider 520. System 500 further includes an input amplifier 590 operatively connected to a clock signal 560 and a clock-bar signal 562. Input amplifier 590 amplifies clock signal 560 and clock-bar signal 562 for delivery to first and second frequency dividers 510, 520. Clock signal 560 and clock-bar signal 562 may be provided by an oscillator (not shown), as provided above in the discussion of FIG. 4.

First frequency divider 510 and second frequency divider 520 should be substantially identical to each other and may be similar to frequency dividers 210, 220, as discussed above in connection with FIG. 2. Thus, first frequency divider 510 may include a first output port 512, a first internal node 514, a clock input 516, and a clock-bar input 518, where the first internal node has a 90° phase shift relative to the first output port. Similarly, second frequency divider 520 may include a second output port 522, a second internal node 524, a clock input 526, and a clock-bar input 528, where the second internal node has a 90° phase shift relative to the second output port. For example, the phase shift of 90° may be locked in each of first and second frequency dividers 510, 520 by respectively connecting first and second clock inputs 516, 526 with clock signal 560 and respectively connecting first and second clock bar inputs 518, 528 with clock bar signal 562, as previously discussed.

First and second symmetrical single-phase frequency dividers 510, 520 may each include a pair of cross-coupled D flip-flop circuits (not shown), operating in a similar manner as presented above in the description of FIG. 2. Hence, one of the pair of cross-coupled flip-flop circuits of each symmetrical single-phase frequency divider 510, 520 receives and divides clock signal 560, while the other flip-flop circuit receives and divides a clock-bar signal 562, as will be discussed further below.

In the illustrative embodiment of FIG. 5, first feedback circuit 530 couples first internal node 514 and second internal node 524 to generate a first internal signal 570 and a second internal signal 572, respectively. Second feedback circuit 540 couples first output port 512 and second output port 522 to generate a first output signal 580 and a second output signal 582, respectively. First feedback circuit 530 may configure a consistent phase-lock of 180° between first internal signal 570 and second internal signal 572. Similarly, second feedback circuit 540 may configure a consistent phase-lock of 180° between first output signal 580 and second output signal 582. Deviations from a phase shift of 180 degrees would affect the integrity and performance of signals 570, 572, 580, 582.

First feedback circuit 530 and second feedback circuit 540 may operate in a similar manner as feedback circuit 230 of FIG. 2. In view of that, first feedback circuit 530 may include a first inverter 532 cross-coupled with a second inverter 534, and second feedback circuit 540 may include a third inverter 542 cross-coupled with a fourth inverter 544. Inverters may include different types of inverters as discussed above in connection with the illustrative embodiment of FIG. 3.

During operation, one of the pair of cross-coupled flip-flop circuits of each frequency divider 510, 520 receives and divides clock signal 560, in similar manner described above in the description of FIGS. 2 and 4. The other flip-flop circuit of each frequency divider 510, 520 receives and divides clock-bar signal 562. First internal node 514 provides first internal signal 570 and first output port 512 provides first output signal 580. First internal signal 570 may be quadrature to first output signal 580, such as a complementary in-phase (I-bar) signal and a complementary quadrature phase (Q-bar) signal, respectively. Similarly, second output port 522 provides a second output signal 582 while second internal node 524 provides a second internal signal 572. Second output signal 582 is a quadrature to second internal signal 572, such as a quadrature phase (Q) signal and an in-phase (I) signal, respectively. First feedback circuit 530 may phase-lock first internal signal 570 to be the complementary of second internal signal 572. Second feedback circuit 540 may phase-lock first output signal 580 to be complementary to second output signal 582. It is noted that the present disclosure contemplates different configurations of signals 570, 572, 580, and 582 without deviating from the scope and spirit of the present disclosure.

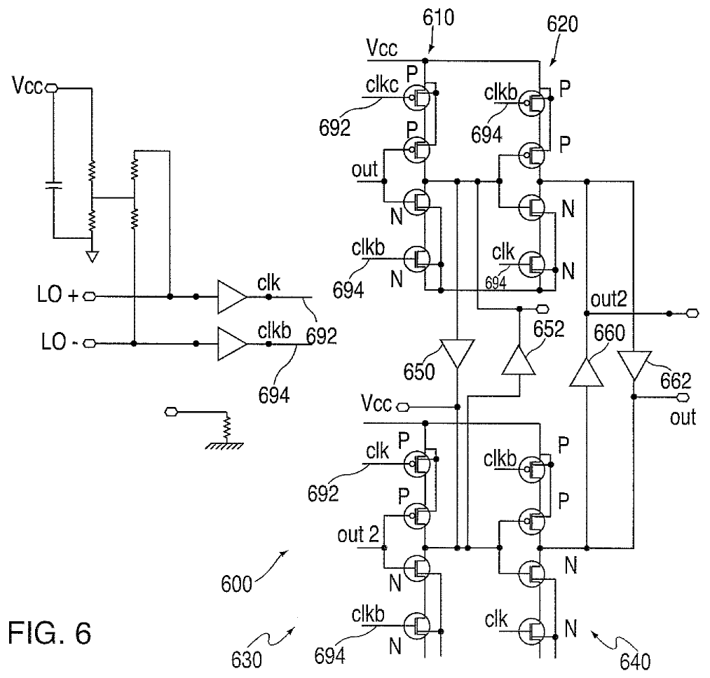

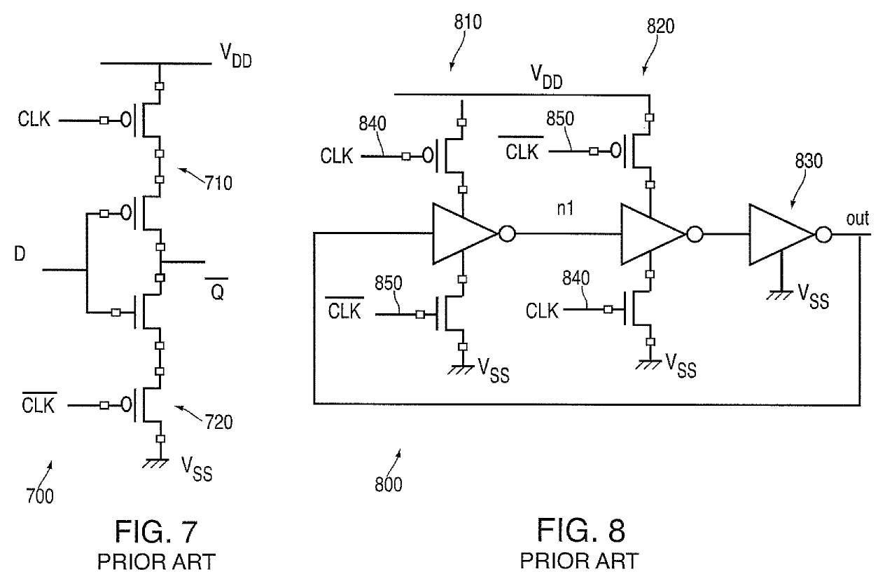

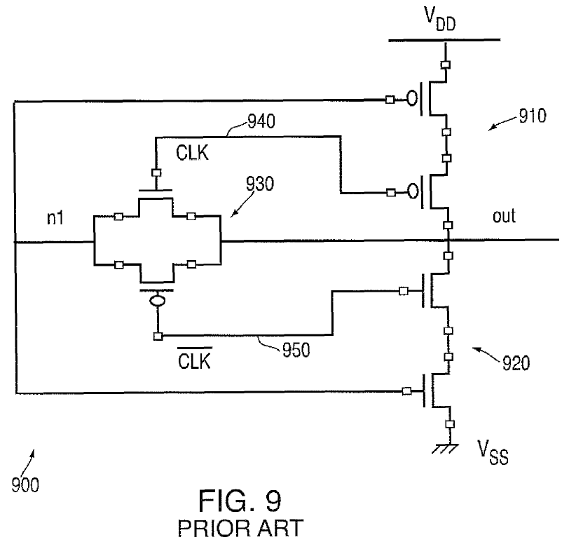

FIG. 6 illustrates a signal generator system 600 according to still another embodiment of the present disclosure. At a high level, system 600, may include, among other things, a first latch 610, a second latch 620, a third latch 630, a fourth latch 640, a first inverter 650, a second inverter 652, a third inverter 660, a fourth inverter 662, and an input amplifier 690 amplifying a clock signal 692 and a clock bar signal 694.

First, second, third and fourth latches 610, 620, 630, and 640 may be identical and form two dynamic CMOS dividers similar to divider 800 of FIG. 8 provided above in the Background of the Invention section. However, third inverter 830 of divider 800 may be combined into four associated identical inverters 650, 652, 660, and 662 in system 600, to form a symmetrical structure for the system and ensure differential operations. The illustrative embodiment of FIG. 6 of the present disclosure provides a topology utilizing four latches, such as latches 610, 620, 630, and 640, and may achieve the functionality of system 400 of FIG. 4. System 400 of FIG. 4 may utilize eight latches, four single-phase dividers, for generating accurate I/Q signals. In the illustrative embodiment of FIG. 6, differential signals may be generated between a first dynamic CMOS divider formed by first latch 610 and second latch 620 and a second dynamic CMOS divider formed by third latch 630 and fourth latch 640. A 90° difference may be generated between a delay of each latch. First, second, third, and fourth latches 610, 620, 630, and 640 may each have the substantially same structure with substantially the same devices connected to each latch. Thus, first, second, third, and fourth latches 610, 620, 630, and 640 may be fully symmetrical with each latch loaded with the same impedance and experiencing the same signal delay. Therefore, first, second, third, and fourth latches 610, 620, 630, and 640 of system 600 generate accurate 0°, 90°, 180°, and 270° signals with perfect amplitude and phase accuracy while consuming less power and occupying less chip area and/or space than conventional systems.

Exemplary embodiments have been disclosed above and illustrated in the accompanying drawings. It will be understood by those skilled in the art that various changes, omissions, and additions may be made to that which is specifically disclosed herein without departing from the spirit and scope of the present invention.

What is claimed is:

1. An integrated circuit, comprising:
a signal generator for generating a plurality of signals of differing phase, said signal generator including:
a first single-phase frequency divider that includes a first output port for providing a first output signal and a first internal node for providing a first internal signal, said first single-phase frequency divider configured to phase-lock said first output signal and said first internal signal 90° apart;
a second single-phase frequency divider that includes a second output port for providing a second output signal and a second internal node for providing a second internal signal, said second single-phase frequency divider configured to phase-lock said second output signal and said second internal signal 90° apart; and
a first feedback circuit coupled between either: 1) said first output port and said second output port or 2) said first internal node and said second internal node;
said first feedback circuit configured to phase-lock said first output signal and said second output signal 180° apart when said first feedback circuit is coupled between said first output port and said second output port; and
said first feedback circuit configured to phase-lock said first internal signal and said second internal signal 180° apart when said first feedback circuit is coupled between said first internal node and said second internal node.

2. The integrated circuit of claim 1, wherein:
said first single-phase frequency divider has a first clock input and a first clock-bar input;
said second single-phase frequency divider has a second clock input and a second clock-bar input; and
the integrated circuit further comprises:
a clock signal connected to each of said first clock input and said second clock input; and
a clock-bar signal connected to each of said first clock-bar input and said second clock-bar input.

3. The integrated circuit of claim 1, wherein:
said first single-phase frequency divider has a first clock input and a first clock-bar input;
said second single-phase frequency divider has a second clock input and a second clock-bar input; and
the integrated circuit further comprises:
a clock signal connected to each of said first clock input and said second clock-bar input; and
a clock-bar signal connected to each of said first clock-bar input and said second clock input.

4. The integrated circuit of claim 1, wherein each of said first single-phase frequency divider and said second single-phase frequency divider is a symmetrical divider;
said signal generator further comprises a second feedback circuit;
said first feedback circuit being coupled between said first output port and said second output port; and
said second feedback circuit coupled between said first internal node and said second internal node.

5. The integrated circuit of claim 4, further comprising a clock signal and a clock-bar signal each in communication with each of said first single-phase frequency divider and said second single-phase frequency divider.

6. The integrated circuit of claim 5, further comprising an input amplifier operatively connected to each of said clock signal and said clock-bar signal.

7. The integrated circuit of claim 4, wherein each of said first feedback circuit and said second feedback circuit comprises a pair of cross-coupled inverters.

8. The integrated circuit of claim 1, wherein each of said first single-phase divider and said second single-phase divider comprises a pair of cross-coupled flip-flop circuits.

9. The integrated circuit of claim 1, wherein said first feedback circuit comprises a pair of cross-coupled inverters.

10. The integrated circuit of claim 1, wherein said signal generator further includes:
a third single-phase frequency divider that includes a third output port for providing a third output signal and a third internal node for providing a third internal signal;
a fourth single-phase frequency divider that includes a fourth output port for providing a fourth output signal and a fourth internal node for providing a fourth internal signal; and
a second feedback circuit coupled between either: 1) said third output port and said fourth output port or 2) said third internal node and said fourth internal node;
said second feedback circuit configured to phase-lock said third output signal and said fourth output signal 180° apart when said second feedback circuit is coupled between said third output port and said fourth output port; and
said second feedback circuit configured to phase-lock said third internal signal and said fourth internal signal 180° apart when said second feedback circuit is coupled between said third internal node and said fourth internal node.

11. The integrated circuit of claim 10, wherein:
said first single-phase frequency divider has a first clock input and a first clock-bar input;
said second single-phase frequency divider has a second clock input and a second clock-bar input;
said three single-phase frequency divider has a third clock input and a third clock-bar input;
said fourth single-phase frequency divider has a fourth clock input and a fourth clock-bar input; and
the integrated circuit further comprises:
a clock signal connected to each of said first clock input, said second clock-bar input, said third clock input, and said fourth clock-bar input; and
a clock-bar signal connected to each of said first clock-bar input, said second clock input, said third clock-bar input, and said fourth clock input.

12. The integrated circuit of claim 10, wherein said signal generator has a first output line for outputting a first generator output signal and a second output line for outputting a second generator output signal phase-shifted 90° with respect to said first generator output signal.

13. The integrated circuit of claim 10, wherein each of said first single-phase frequency divider, said second single-phase frequency divider, said third single-phase frequency divider, and said fourth single-phase frequency divider comprises a pair of cross-coupled flip-flop circuits.

14. The integrated circuit of claim 1, wherein said signal generator has a first output line for outputting a first generator output signal and a second output line for outputting a second generator output signal phase-shifted 90° with respect to said first generator output signal.

15. An I/Q signal generator, comprising:
a signal generation circuit responsive to a clock signal and a clock-bar signal so as to generate an in-phase signal and a quadrature-phase signal, said signal generation circuit including:
a plurality of single-phase frequency dividers each including an output port for providing an output signal and an internal node for providing an internal signal, each said single-phase frequency divider configured to phase-lock said output signal and said internal signal 90° apart;
an in-phase output line and a quadrature-phase output line each in direct communication with differing ones of said output ports and said internal nodes; and
first and second 180° phase-lock circuits each coupled between ones of said plurality single-phase frequency dividers so that said in-phase signal outputs said in-phase signal and said quadrature-phase output line outputs said quadrature-phase signal.

16. The I/Q signal generator of claim 15, wherein:
the signal generation circuit comprises first and second symmetrical single-phase frequency dividers;
said first 180° phase-lock circuit is coupled between said output ports of said first and second symmetrical single-phase frequency dividers;
said second 180° phase-lock circuit is coupled between said internal nodes of said first and second symmetrical single-phase frequency dividers;
said in-phase output line is in direct communication with one of said output port and said internal node of said first symmetrical single-phase divider; and
said quadrature-phase output line is in direct communication with the other of said output port and said internal node of said first symmetrical single-phase divider.

17. The I/Q signal generator of claim 15, wherein:
the signal generation circuit comprises first, second, third and fourth single-phase frequency dividers;
said first 180° phase-lock circuit is coupled between said first and second single-phase frequency dividers;
said second 180° phase-lock circuit is coupled between said third and fourth single-phase frequency dividers;
said in-phase output line is in direct communication with said first single-phase frequency divider; and
said quadrature-phase output line is in direct communication with said third single-phase frequency divider.

18. A method of generating an in-phase signal and a corresponding quadrature-phase signal, comprising:
receiving a clock signal having a frequency;
generating an in-phase signal as a function of said clock signal so that said in-phase signal has a frequency equal to one-half of said frequency of said clock signal;
generating a quadrature-phase signal as a function of said clock signal so that said quadrature-phase signal has a frequency equal to one-half of said frequency of said clock signal;
phase-locking said in-phase signal to a complementary in-phase signal; and
phase-locking said quadrature-phase signal to a complementary quadrature-phase signal.

19. The method of claim 18, further comprising generating each of said complementary in-phase signal and said complementary quadrature-phase signal using a single-phase frequency divider.

20. The method of claim 18, further comprising generating said complementary in-phase signal using a first single-phase frequency divider and generating said complementary quadrature-phase signal using a second single-phase frequency divider.
